(19) United States
(12) Patent Application Publication
(10) Pub. No.: US 2023/0070489 A1
(43) Pub. Date: Mar. 9, 2023

(54) DOPED TANTALUM-CONTAINING BARRIER FILMS

(71) Applicant: Applied Materials, Inc., Santa Clara, CA (US)

(72) Inventors: Michael Haverty, Mountain View, CA (US); Lu Chen, Cupertino, CA (US); Muthukumar Kaliappan, Fremont, CA (US)

(73) Assignee: Applied Materials, Inc., Santa Clara, CA (US)

(21) Appl. No.: 17/845,356

(22) Filed: Jun. 21, 2022

Related U.S. Application Data
(60) Provisional application No. 63/242,266, filed on Sep. 9, 2021.

(51) Int. Cl. H01L 23/532; H01L 21/768; H01L 21/285

(52) U.S. Cl. CPC H01L 23/53266; H01L 21/76846; H01L 21/76877; H01L 21/28556

(57) ABSTRACT

Described are microelectronic devices and methods for forming interconnections in microelectronic devices. Embodiments of microelectronic devices include tantalum-containing barrier films comprising an alloy of tantalum and a metal dopant selected from the group consisting of ruthenium (Ru), osmium (Os), palladium (Pd), platinum (Pt), and iridium (Ir).

### CROSS-REFERENCE TO RELATED APPLICATIONS

The present application claims priority to U.S. patent application Ser. No. 63/242,266 filed on Sep. 9, 2021.

### TECHNICAL FIELD

Embodiments of the disclosure generally relate to methods of treating and/or doping barrier films. More particularly, embodiments of the disclosure are directed to methods of treating and doping tantalum-containing barrier films with a metal dopant.

### BACKGROUND

Microelectronic devices, such as semiconductors or integrated circuits, can include millions of electronic circuit devices such as transistors, capacitors, etc. To further increase the density of devices found on integrated circuits, even smaller feature sizes are desired. To achieve these smaller feature sizes, the size of conductive lines, vias, and interconnects, gates, etc. must be reduced. Reliable formation of multilevel interconnect structures is also necessary to increase circuit density and quality. Advances in fabrication techniques have enabled use of copper for conductive lines, interconnects, vias, and other structures. However, electromigration in interconnect structures becomes a greater hurdle to overcome, with decreased feature size and the increased use of copper for interconnections. Such electromigration may adversely affect the electrical properties of various components of the integrated circuit.

Interconnect and via structures typically utilize a low resistivity metal to conduct electrons in a three-dimensional integrated circuit. To minimize crosstalk between the metal lines, a dielectric layer is used between the metal lines. However, the atoms in interconnect lines can diffuse through the dielectric layer if the interconnect lines and the dielectric layer are in direct contact. A barrier film between interconnects and dielectrics helps prevent the diffusion of atoms. Tantalum nitride is a commonly used barrier film material.

While transistor performance improves with scaling, interconnect via resistance can increase by a factor of 10. This results in resistive-capacitive (RC) delays that reduce performance. Improving interconnect resistance at small geometries can occur with new metal fill processes that improve the properties of high resistivity barriers and liners. Accordingly, there is a need to provide improved barrier materials to improve the performance of interconnects.

### SUMMARY

Embodiments of the disclosure provide microelectronic devices comprising: a dielectric layer on a substrate, the dielectric layer comprising at least one feature defining a gap; a barrier film comprising an alloy of tantalum and a metal dopant selected from the group consisting of ruthenium (Ru), osmium (Os), palladium (Pd), platinum (Pt), and iridium (Ir) on the dielectric layer; a metal liner film on the barrier film; and a gap fill metal on the metal liner film.

Additional embodiments of the disclosure are directed to methods of forming interconnections in microelectronic devices. In one or more embodiments, the methods comprise forming a dielectric layer on a substrate, the dielectric layer comprising at least one feature defining a gap; forming a barrier film on the dielectric layer, the barrier film comprising an alloy of tantalum and a metal dopant selected from the group consisting of ruthenium (Ru), osmium (Os), palladium (Pd), platinum (Pt), and iridium (Ir); depositing a metal liner film on the barrier film; and depositing a conductive gap fill metal on the metal liner film.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process flow diagram of a method for forming interconnections in a microelectronic device according to one or more embodiments of the disclosure;

FIG. 2 illustrates a portion of a microelectronic device during a stage of manufacture with one or more embodiments having a dielectric layer on a substrate;

FIG. 3A illustrates a tantalum-containing barrier film formed on the dielectric layer shown in FIG. 2;

FIG. 3B illustrates a metal liner film deposited on the tantalum-containing barrier film formed in FIG. 3A;

FIG. 3C illustrates a conductive gap fill deposited on the metal liner film formed in FIG. 3B; and

FIG. 4 illustrates a cross-sectional view of a cluster tool in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

It has advantageously been found that the adhesion of the tantalum-containing barrier film can be improved by forming a tantalum-containing barrier film comprising an alloy of tantalum and a metal dopant selected from the group consisting of ruthenium (Ru), osmium (Os), palladium (Pd), platinum (Pt), and iridium (Ir).

In one or more embodiments, the tantalum-containing barrier film may be deposited via ALD. In a typical ALD process, alternating pulses or flows of “A” precursor and “B” precursor can be used to deposit a film. The alternating exposure of the surface to reactants “A” and “B” is continued until the desired thickness film is reached. However, instead of pulsing the reactants, the gases can flow simultaneously from one or more gas delivery head or nozzle and the substrate and/or gas delivery head can be moved such that the substrate is sequentially exposed to each of the reactive gases. Of course, the aforementioned ALD cycles are merely exemplary of a wide variety of ALD process cycles in which a deposited layer is formed by alternating layers of precursors and co-reactants.

In one or more embodiments, the co-reactants are in vapor or gas form. The reactants may be delivered with a carrier gas. A carrier gas, a purge gas, a deposition gas, or other process gas may contain nitrogen, hydrogen, argon, neon, helium, or combinations thereof. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

In one or more embodiments, the barrier metal material and the metal dopant are deposited using a multi-chamber process with separation of the tantalum-containing barrier film material (e.g., tantalum) and the metal dopant. In other embodiments, a single chamber approach is used, with all processes occurring within one chamber and the different layers separated in processing by gas purges.

Some embodiments of the disclosure are directed to barrier applications, e.g., copper barrier applications. The barrier film formed by one or more embodiments may be used as a copper barrier. Suitable barrier films for copper barrier applications include, but are not limited to, tantalum-containing barrier films. For copper barrier applications, suitable metal dopants include, but are not limited to, ruthenium (Ru), osmium (Os), palladium (Pd), platinum (Pt), and iridium (Ir) or combinations thereof.

A plasma treatment can be used after doping to promote removing film impurities and improving the density of the tantalum-containing barrier film. In other embodiments, post treatment can include, but is not limited to, physical vapor deposition (PVD) treatment, thermal anneal, chemical enhancement, or the like. In one or more embodiments, post treatment including PVD treatment removes nitride from the tantalum-containing barrier film. In some copper barrier applications, a high frequency plasma (defined as greater than about 14 MHz or about 40 MHz or greater) can be used with any inert gas, including, but not limited to, one or more of neon (Ne), hydrogen (H₂), and argon (Ar) gas. In one or more embodiments, to prevent low-k damage, a higher plasma frequency can be used (higher than 13.56 MHz). In some embodiments, the tantalum-containing barrier film is a copper barrier and comprises Ta doped with Ru.

Suitable precursors for depositing a tantalum-containing barrier film include metal-containing precursors and in some embodiments, nitrogen-containing precursors. In one or more embodiments, forming the alloy of tantalum and the metal dopant comprising ruthenium (Ru) comprises separately co-flowing a tantalum-containing precursor and a ruthenium-containing precursor. For example, the tantalum-containing precursor may be pentakis(dimethylamino)tantalum (PDMAT) and in some embodiments, a nitrogen-containing precursor may be ammonia (NH₃). In some embodiments, the tantalum-containing barrier film contains regions of tantalum nitride as well as an alloy of the dopant metal and tantalum. Other suitable precursors are known to those skilled in the art. Organic species in organic-containing precursors for barrier films may get partially incorporated into the underlying layer (such as a dielectric layer), which may increase the adhesion at the barrier film-underlying layer interface.

In one or more embodiments, the metal dopant may be incorporated into the barrier film by any suitable method known to the skilled artisan. For example, in one or more embodiments, the metal dopant may be incorporated into the tantalum-containing barrier film by one or more of alternating and/or co-flowing of precursors in atomic layer deposition (ALD), chemical vapor deposition (CVD), and plasma enhanced atomic layer deposition (PEALD); precursors with multi-metal ligands; and dopant implanting/thermal diffusion. In one or more embodiments, when the metal dopant is incorporated into the barrier film by alternating and/or co-flowing of precursors in atomic layer deposition (ALD), chemical vapor deposition (CVD), and plasma enhanced atomic layer deposition (PEALD), an appropriate metal-containing precursor may be used.

Examples of suitable precursors include metal complexes containing the desired dopant, such as metal dopants coordinated with organic or carbonyl ligands. In one or more embodiments, a dopant precursor may comprise a multi-metal ligand. A suitable dopant precursor should have sufficient vapor pressure to be deposited in the appropriate process, such as ALD, plasma enhance atomic layer deposition (PEALD), or chemical vapor deposition (CVD). In one or more embodiments, the metal dopant comprises osmium (Os) formed by an atomic layer deposition (ALD) process. In one or more embodiments, the dopant is deposited using a chemical vapor deposition (CVD) process. In one or more embodiments, the metal dopant comprising ruthenium (Ru) is formed by a chemical vapor deposition (CVD) process.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Depending on the dopant precursor used, a co-reactant may be used to deposit the dopant. For example, reducing gases such as hydrogen and ammonia can be used as co-reactants for depositing some dopants. Metal dopant precursors and co-reactants may be either co-flowed or flowed sequentially.

In one or more embodiments, ion implantation may be used for incorporating the metal dopant into the barrier film. In other embodiments, physical vapor deposition (PVD) co-treatment may be used to add a second metal dopant, e.g., cobalt (Co), into the barrier film. In further embodiments, the barrier film may be annealed inside an atmosphere comprising the metal dopant to thermally diffuse the dopant into the film. In one or more embodiments, the dopant is not limited to a metal. In one or more embodiments, a non-metal can also be a dopant, for example, silicon (Si), boron (B), or the like. Non-metal dopants may also be used for thermal diffusion.

In some embodiments, instead of or in addition to using a reducing gas co-reactant, a post-plasma treatment step may be used after exposing the barrier film to the metal dopant precursor. According to one or more embodiments, the plasma comprises any suitable inert gas known to the skilled artisan. In one or more embodiments, the plasma comprises one or more of helium (He), argon (Ar), ammonia (NH₃), hydrogen (H₂), and nitrogen (N₂). In some embodiments, the plasma may comprise a mixture of Ar and H₂, such as a mixture having an Ar:H₂ molar ratio in the range from 1:1 to 1:10. The plasma power may be in the range from about 200 to about 1000 Watts. The plasma frequency may be in the range from 350 kHz to 40 MHz. The plasma treatment time may vary from 5 second to 60 seconds, such as in the range from 10 seconds to 30 seconds. In some embodiments, the pressure during plasma treatment may be in the range from 0.5 to 50 Torr, such as from 1 to 10 Torr. In some embodiments, the wafer spacing may be in the range from 100 mils to 600 mils.

In one or more embodiments, the barrier film may be exposed to the metal dopant precursor during deposition, i.e., the metal dopant precursor may be used sequentially in the ALD cycle to provide a doped barrier film. For example, 1-10 cycles of metal-containing precursors and nitrogen-containing precursors can be used to form an initial metal nitride barrier film, followed by exposure to 1-10 cycles of the metal dopant precursor, then resuming cycles of the metal-containing precursors and nitrogen-containing precursors, then optionally more doping, etc., until the desired doped barrier film thickness is reached. Alternatively, in other embodiments, the barrier film may be completely deposited to the desired thickness before exposing to the metal dopant precursors.

In various embodiments, the duration of the exposure to the metal dopant precursor may range from 1 to 60 seconds, such as in the range from 3 to 30 seconds or from 5 to 10 seconds. Longer exposures to the metal dopant precursor will increase the amount of doping of the barrier film, as long as the barrier film has not reached the maximum doping for the density of the barrier film.

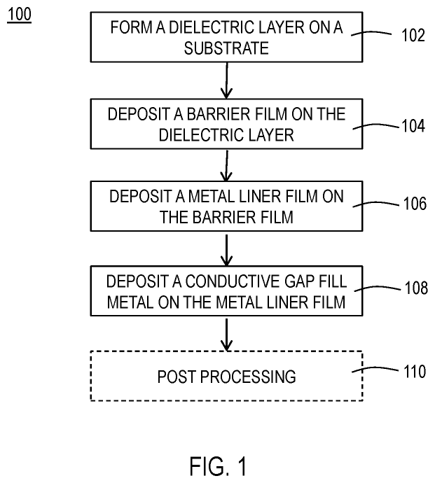

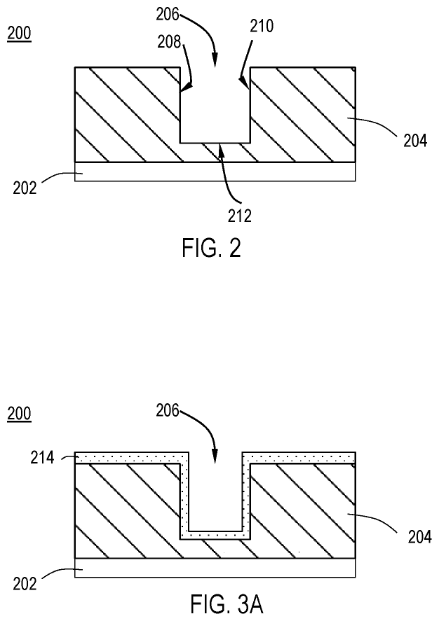

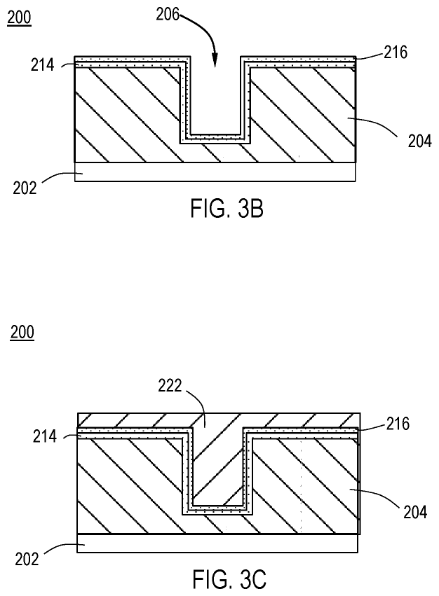

FIG. 1 illustrates a process flow diagram of a method for forming interconnections in a microelectronic device according to one or more embodiments. FIGS. 2 through 3C illustrate portions of a microelectronic device 200 during stages of manufacture. Referring to FIGS. 1 and 2, at operation 102, a dielectric layer 204 is formed on a substrate 202. In one or more embodiments, the dielectric layer 204 may comprise at least one feature 206. In one or more embodiments, the at least one feature 206 comprises a bottom 212 and a first sidewall 208 and a second sidewall 210. The Figures show substrates having a single feature for illustrative purposes; however, those skilled in the art will understand that there can be more than one feature. The shape of the feature 206 can be any suitable shape including, but not limited to, trenches and cylindrical vias. As used in this regard, the term “feature” means any intentional surface irregularity. Suitable examples of features include, but are not limited to, trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

In one or more embodiments, the dielectric layer 204 is a low-k dielectric layer. In certain embodiments, the dielectric layer 204 comprises silicon oxide (SiOₓ). Further embodiments provide that the dielectric layer 204 comprises porous or carbon-doped SiOₓ. In some embodiments, the dielectric layer 204 is a porous or carbon-doped SiOₓ layer with a k value less than about 5. In other embodiments, the dielectric layer 204 is a multilayer structure. For example, in one or more embodiments, the dielectric layer 204 comprises a multilayer structure having one or more of a dielectric layer, an etch stop layer, and a hard mask layer.

With reference to FIGS. 1 through 3C, at operation 104 a tantalum-containing barrier film 214 is deposited on the dielectric layer 204 on the substrate 202. In some embodiments, the barrier film 214 is formed by a conformal deposition process. In some embodiments, the barrier film 214 is formed by one or more of atomic layer deposition (ALD) or chemical vapor deposition (CVD). In one or more embodiments, the barrier film 214 is deposited by atomic layer deposition (ALD), and has a thickness in a range of from 8 Å to 10 Å. In some embodiments, the barrier film 214 is deposited in a single ALD cycle. In other embodiments, the barrier film 214 is deposited in from 1 to 15 ALD cycles.

In one or more embodiments, the deposition of the tantalum-containing barrier film 214 is substantially conformal. In one or more embodiments, the tantalum-containing barrier film 214 forms on the first sidewall 208, the second sidewall 210, and the bottom 212 of the at least one feature. As used herein, a layer which is “substantially conformal” refers to a layer where the thickness is about the same throughout (e.g., on the top, middle and bottom of sidewalls and on the bottom of the opening 206). A layer which is substantially conformal varies in thickness by less than or equal to about 5%, 2%, 1% or 0.5%.

In one or more embodiments, the tantalum-containing barrier film 214 comprises an alloy of tantalum and a metal dopant selected from the group consisting of ruthenium (Ru), osmium (Os), palladium (Pd), platinum (Pt), and iridium (Ir). In one or more embodiments, the metal dopant comprising ruthenium is present in the tantalum-containing barrier film 214 at less than 30 atomic %, less than 20 atomic %, less than 10 atomic %, or less than 5 atomic %. In one or more embodiments, the metal dopant comprising osmium is present in the tantalum-containing barrier film 214 at less than 20 atomic %, less than 15 atomic %, less than 10 atomic %, or less than 5 atomic %. In one or more embodiments, the metal dopant comprising palladium is present in the tantalum-containing barrier film 214 at less than 10 atomic %, or less than 5 atomic %. In one or more embodiments, the metal dopant comprising platinum is present in the tantalum-containing barrier film 214 at less than 5 atomic %, less than 3 atomic %, less than 2 atomic %, or less than 1 atomic %. In one or more embodiments, the metal dopant comprising iridium is present in the tantalum-containing barrier film 214 at less than 5 atomic %, less than 3 atomic %, less than 2 atomic %, or less than 1 atomic %.

Without intending to be bound by theory, forming an alloy of tantalum and a metal dopant selected from the group consisting of ruthenium (Ru), osmium (Os), palladium (Pd), platinum (Pt), and iridium (Ir) forms a tantalum-containing barrier film that does not experience a change in crystalline structure, the tantalum-containing barrier film staying below a saturation limit of the alloy of tantalum and the metal dopant. In one or more embodiments, the saturation limit of the alloy of tantalum and the metal dopant may be shown by a solidus line on a binary phase diagram. In one or more embodiments, the metal dopant comprising (Ru) is present in the tantalum-containing barrier film 214 at less than 20 atomic %. In one or more embodiments, the barrier film 214 is substantially free of an intermetallic compound of tantalum and the metal dopant comprising (Ru) when the metal dopant comprising (Ru) is present in the barrier film 214 at less than 20 atomic %. As used herein, “substantially free” refers to less than 1% by weight. The tantalum-containing barrier film also comprises tantalum nitride, which in some embodiments, is in separate regions of the film from the Ru-doped tantalum. Stated another way, the tantalum-containing barrier film comprises a composite region comprising regions of undoped TaN and regions of alloys of tantalum and a metal dopant selected from the group consisting of ruthenium (Ru), osmium (Os), palladium (Pd), platinum (Pt), and iridium (Ir). In some embodiments, the tantalum-containing barrier film comprises a composite region comprising regions of undoped TaN and regions of Ru-Ta alloys. In some embodiments, the film comprises an RuₓTa_{y} intermetallic compound (e.g., TaₓRu_{y}N or TaₓRu_{y}N_{z}O), however, in specific embodiments, it is believed that a film that is substantially free of a RuₓTa_{y} intermetallic compound exhibits improved properties compared to a film that includes a RuₓTa_{y} intermetallic compound.

In one or more embodiments, the metal dopant is added to prevent formation of a stable nitride in the barrier film 214. As used in this specification and appended claims, the term “stable nitride” refers to a nitride-containing compound that does not react with other compounds or a compound that is formed when a metal atom is in the presence of nitrogen atoms. For example, a nitride that is not a stable nitride may result in a nitrogen-containing compound (e.g., tantalum nitride) bonding with a metal atom (e.g., ruthenium). In one or more embodiments, the nitrogen-containing compound (e.g., tantalum nitride) bonded to the metal atom (e.g., ruthenium) reacts with other compounds to form a bond with another, different metal atom or non-metal atom. In one or more embodiments, metal dopants selected from the group consisting of ruthenium (Ru), osmium (Os), palladium (Pd), platinum (Pt), and iridium (Ir) do not form stable nitrides in the barrier film 214. Without intending to be bound by theory, it is believed that metal dopants comprising one or more of iron (Fe) and rhenium (Re) form weakly stable nitrides. Without intending to be bound by theory, it is believed that metal dopants comprising one or more of gallium (Ga), hafnium (Hf), niobium (Nb), silicon (Si), titanium (Ti), vanadium (V), tungsten (W), and molybdenum (Mo) form stable nitrides.

In one or more embodiments, the metal dopant has a density that is greater than a density of an undoped barrier film comprising tantalum nitride. It has been advantageously found that the metal dopant comprising ruthenium (Ru) has a density that is at least 15%, 10%, or 5% greater than the density of the undoped film. Without intending to be bound by theory, it is believed that increasing the density of the barrier film 214 improves barrier properties.

In one or more embodiments, the metal dopant diffuses through the barrier fill 214 to the dielectric layer 204. Without intending to be bound by theory, it is thought that the metal dopant can selectively diffuse through the barrier film 214 to the dielectric layer and form a complex with the dielectric material that will be resistant to electromigration. One proposed mechanism is that the exposed precursor and/or an individual disassociated metal atom can preferentially migrate to the dielectric/barrier interface via grain boundaries or other weak paths.

In one or more embodiments, the complex formed may be a metal oxide (MOₓ) or a metal silicate (MSiₓO). Thus, in embodiments where the dopant is ruthenium (Ru) and the dielectric layer 204 comprises silicon oxide (SiOₓ), the ruthenium (Ru) can diffuse through the barrier film 214 and form ruthenium oxide (RuOₓ) or ruthenium silicon oxide (RuSiOₓ). This barrier film 214 of ruthenium silicon oxide (RuSiOₓ) can then prevent copper electromigration from the conductive gap fill metal 222 to the dielectric layer 204.

In addition to being a conductive gap fill metal 222 barrier, the tantalum-containing barrier film 214 may also be a barrier to oxygen diffusing from the dielectric layer 204 to the conductive material 222. Oxygen diffusion from the dielectric layer 204 to the conductive gap fill metal 222 can result in oxygen reacting with component in the conductive gap fill metal 222and/or seed layer (not illustrated). For example, if the conductive gap fill metal 222 comprises copper (Cu), then oxygen can react with the copper at the interface of the barrier film and the conductive gap fill metal 222, thus pinning the copper to the barrier film/conductive material interface. As a result, the copper cannot segregate throughout the conductive gap fill metal. Similarly, if a seed layer comprising copper is present, then oxygen can react with the copper in the seed layer at the seed layer/barrier film interface and pin the copper to the interface.

In one or more embodiments, it is thought that oxygen diffusing into the barrier film will react with the dopant and will prevent oxygen from diffusing into the conductive gap fill metal 222. As a result, oxygen will not be available to react with the seed layer or the conductive gap fill metal 222. In one or more embodiments, the presence of oxygen atoms and/or carbon atoms may degrade the barrier properties of the barrier film 214. As used in this specification and the appended claims, a material, film or layer which comprises “substantially no” atoms of a given element, comprises less than or equal to about 10%, less than or equal to about 5%, less than or equal to about 2%, less than or equal to about 1%, less than or equal to about 0.5%, or less than or equal to about 0.1% of the stated element on an atomic basis. In one or more embodiments, the barrier film 214 comprises substantially no oxygen atoms or carbon atoms.

One or more embodiments provide that depositing the barrier film 214 comprises depositing alternating layers comprising tantalum and metal dopant selected from the group consisting of ruthenium (Ru), osmium (Os), palladium (Pd), platinum (Pt), and iridium (Ir). The doped tantalum-containing film may be formed by any appropriate deposition process. For example, the tantalum can be deposited by an alternating layer deposition (ALD) process, or a plasma enhanced atomic layer deposition (PEALD). The metal dopant can then be deposited by chemical vapor deposition (CVD), physical vapor deposition (PVD) or ALD. The metal dopant is then diffused into the tantalum film to form an integrated tantalum-metal dopant film. The metal dopant may be diffused into the tantalum film through various processes, including by plasma treatment and by heating. The tantalum and the metal dopant may be deposited in alternating layers until a tantalum-containing barrier film of a desired thickness is formed.

FIG. 3A illustrates the portion of the microelectronic device 200 after deposition of a tantalum-containing barrier film 214, which covers at least a portion of the first sidewall 208, the second sidewall 210 and the bottom 212 of the at least one feature 206. As illustrated in FIG. 3A, the barrier film 214 may cover the entirety of the first sidewall 208, the second sidewall 210 and the bottom 212 of the at least one feature 206.

With reference to FIG. 1 and FIG. 3B, at operation 106, a metal liner film 216 is deposited on the barrier film 214. According to one or more embodiments, the metal liner film 216 can be formed by depositing metals or co-reacting metal precursors by CVD, PVD or ALD. Depending on the liner metals used, a co-reactants or co-precursors may be used to deposit the metal liner film 216. In one or more embodiments, the deposition of the metal liner film 216 is substantially conformal. As illustrated in FIG. 3B, the metal liner film 216 may cover the entirety of the first sidewall 208, the second sidewall 210 and the bottom 212 of the at least one feature 206.

In one or more embodiments, the metal liner film 216 can have the same properties as the barrier film 214. In one or more embodiments, each of the barrier film 214 and the metal liner film 216 comprise the alloy of tantalum and the metal dopant comprising osmium (Os). In one or more embodiments, the metal liner film 216 comprising the alloy of tantalum and the metal dopant comprising osmium (Os) improves nucleation of copper compared with a tantalum metal liner film that does not include osmium (Os).

Embodiments of the disclosure provide a portion of a microelectronic device having a multilayer barrier film. In one or more embodiments, the multilayer barrier film comprises a first tantalum-containing barrier film and a second tantalum-containing barrier film. Some embodiments comprise forming the barrier film on the dielectric layer further comprises forming a first barrier film on a substrate by atomic layer deposition, doping the first barrier film with a metal dopant by exposing the first tantalum-containing barrier film to a metal precursor during a flash chemical vapor deposition process to form a doped first barrier film; and forming a second barrier film on the doped first barrier film by one or more of atomic layer deposition to form a doped barrier film. In a non-illustrated embodiment, the second barrier film is deposited on the barrier film 214 to form the doped barrier film. In one or more embodiments, the second barrier film comprises the same material as the barrier film 214.

In one or more embodiments, the doped barrier film is deposited by chemical vapor deposition and has a thickness in a range of from about 1 Å to about 3 Å. In one or more embodiments, the doped barrier film comprises in a range of from about 0.01 to about 50 wt. % dopant, based on the total weight of the barrier film. In certain embodiments, the doped barrier film comprises a range of from about 5% to about 70% dopant, such as a range of from about 10 to about 30 wt. % dopant, such as a range of from about 8 to about 25 wt. % dopant, or a range of from about 10 to about 20 wt. % dopant. In some embodiments, the barrier film 214 comprises a range of from about 5 to about 30 wt. % dopant, such as about 5 wt. %, about 6 wt. %, about 7 wt. %, about 8 wt. %, about 9 wt. %, about 10 wt. %, about 11 wt. %, about 12 wt. %, about 13 wt. %, about 14 wt. %, 15 wt. %, about 16 wt. %, about 17 wt. %, about 18 wt. %, about 19 wt. %, about 20 wt. %, about 21 wt. %, about 22 wt. %, about 23 wt. %, about 24 wt. %, 25 wt. %, about 26 wt. %, about 27 wt. %, about 28 wt. %, about 29 wt. %, or about 30 wt. % dopant.

In one or more embodiments, the second barrier film is deposited by atomic layer deposition (ALD), and has a thickness in a range of from about 2 Å to about 6 Å. In some embodiments, the second barrier film is deposited in a single ALD cycle. In other embodiments, the second barrier film is deposited in from 1 to 15 ALD cycles.

In one or more embodiments, the doped barrier film, which comprises the barrier film 214, doped barrier film, and second barrier film, has a combined thickness in a range of from about 5 Å to about 15 Å, or from about 8 Å to about 10 Å. In further embodiments, the combined thickness is less than about 15 Å. In one or more embodiments, the doped barrier film has a high metal content and an amorphous crystallinity. Without intending to be bound by theory, it is thought that doping a tantalum-containing barrier film reduces the ALD crystallinity of the deposited barrier film, which could reduce diffusion shortcut on grain boundary. Doping within the barrier film instead of on top of the barrier may mitigate integration and corrosion risks due to minimal dopant diffusion.

In one or more embodiments, the doped barrier film comprises a metal dopant in a tantalum-containing barrier film, where the metal dopant is an amorphous matrix of nanocrystallites. In specific embodiments, the doped tantalum barrier film comprises a ruthenium (Ru) in a tantalum nitride film, where the ruthenium (Ru) is an amorphous matrix of nanocrystallites. The doped barrier film of one or more embodiments shows better diffusion barrier properties than a tantalum-containing barrier film that is not doped. Additionally, the doped barrier film of one or more embodiments, demonstrates superior adhesion to copper and oxide.

With reference to FIGS. 1 and 3C, at operation 108, a conductive gap fill metal 222 fills at least a portion of the trench 206 lined with the barrier film 214 and the metal liner film 216. According to one or more embodiments, the conductive gap fill metal 222 comprises copper (Cu) or a copper alloy. In further embodiments, the conductive gap fill metal 222 also comprises manganese (Mn). In other embodiments, the conductive gap fill metal 222 further comprises aluminum (Al). In some embodiment, the conductive gap fill metal 222 comprises tungsten (W).

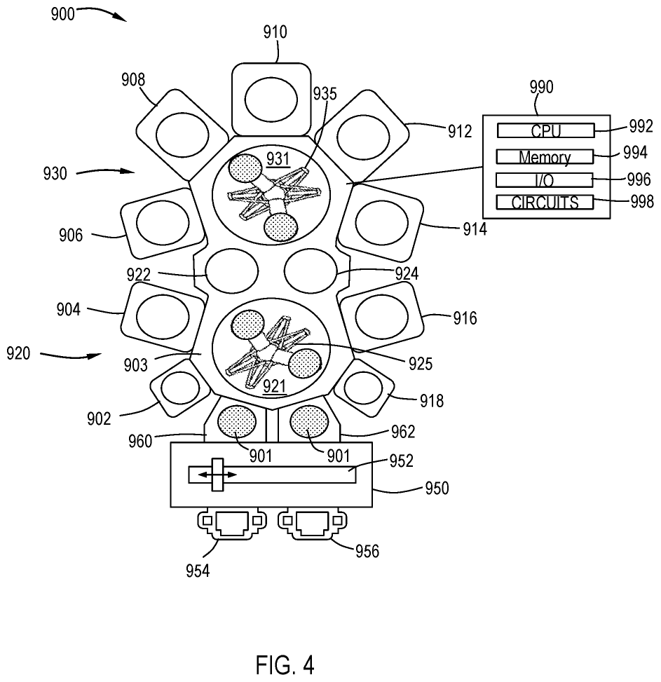

Although the conductive gap fill metal 222 in FIG. 4 is shown in direct contact with the metal liner film 216, intermediate layers may be in between the conductive gap fill metal 222 and the metal liner film 216, such as adhesion layers or seeding layers. For example, in one or more embodiments, the microelectronic device 200 further comprises an adhesion layer comprising a metal dopant selected from the group consisting of ruthenium (Ru), osmium (Os), palladium (Pd), platinum (Pt), and iridium (Ir). In certain embodiments, a seeding layer (not illustrated) may be deposited on top of the metal liner film 216. According to one or more embodiments, the seeding layer can comprise an alloy of copper, such as a Cu—Ta alloy or a Cu—Mn alloy.

At operation 110, the portion of the microelectronic device 200 is optionally post-processed. The optional post-processing operation 110 can be, for example, a process to modify film properties (e.g., annealing) or a further film deposition process (e.g., additional ALD or CVD processes) to grow additional films. In some embodiments, the optional post-processing operation 110 can be a process that modifies a property of the deposited film. In some embodiments, the optional post-processing operation 110 comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. In some embodiments, the deposition of the barrier film and the dopant film can be done in a single chamber, and then the post-processing can be performed in a separate chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Additional embodiments of the disclosure are directed to processing tools 900 for the formation of the devices and practice of the methods described, as shown in FIG. 4. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, an atomic layer deposition chamber, a chemical vapor deposition chamber, an annealing chamber, and the like. The particular arrangement of process chambers and components can be varied depending on the cluster tool and should not be taken as limiting the scope of the disclosure.

In the embodiment shown in FIG. 4, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo-cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU) 992, memory 994, inputs/outputs (I/O) 996, and support circuits 998. The controller 990 may control the processing tool 900 directly, or via computers (or controllers) associated with particular process chamber and/or support system components.

In one or more embodiments, the controller 990 may be one of any form of general-purpose computer processor that can be used in an industrial setting for controlling various chambers and sub-processors. The memory 994 or computer readable medium of the controller 990 may be one or more of readily available memory such as non-transitory memory (e.g., random access memory (RAM)), read only memory (ROM), floppy disk, hard disk, optical storage media (e.g., compact disc or digital video disc), flash drive, or any other form of digital storage, local or remote. The memory 994 can retain an instruction set that is operable by the processor (CPU 992) to control parameters and components of the processing tool 900.

The support circuits 998 are coupled to the CPU 992 for supporting the processor in a conventional manner. These circuits include cache, power supplies, clock circuits, input/output circuitry and subsystems, and the like. One or more processes may be stored in the memory 994 as software routine that, when executed or invoked by the processor, causes the processor to control the operation of the processing tool 900 or individual processing units in the manner described herein. The software routine may also be stored and/or executed by a second CPU (not shown) that is remotely located from the hardware being controlled by the CPU 992.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the controller 990 has one or more configurations to execute individual processes or sub-processes to perform the method. The controller 990 can be connected to and configured to operate intermediate components to perform the functions of the methods. For example, the controller 990 can be connected to and configured to control a physical vapor deposition chamber.

Processes may generally be stored in the memory 994 of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the system controller 990 has a configuration to control an atomic layer deposition chamber to deposition a tantalum-containing barrier film on a substrate. The system controlled 990 has a second configuration to control a chemical vapor deposition chamber to deposit a metal film on the barrier film at a temperature in the range of about 20° C. to about 400° C.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a deposition chamber, a plasma treatment chamber, a remote plasma source, an annealing chamber, and a controller connected to the central transfer station and the plurality of process stations, the controller configured to activate the robot to move the wafer between process stations, and to control a process occurring in each of the process stations.

Some embodiments provide non-transitory computer readable mediums which cause a processing system to form interconnections in microelectronic devices. In one or more embodiments, a non-transitory computer readable medium including instructions, that, when executed by a controller of a processing system, causes the processing system to perform operations of: f forming a dielectric layer on a substrate, the dielectric layer comprising at least one feature defining a gap; forming a tantalum-containing barrier film on the dielectric layer, the barrier film comprising an alloy of tantalum and a metal dopant selected from the group consisting of ruthenium (Ru), osmium (Os), palladium (Pd), platinum (Pt), and iridium (Ir); depositing a metal liner film on the barrier film; and depositing a conductive gap fill metal on the metal liner film.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A microelectronic device comprising:
a dielectric layer on a substrate, the dielectric layer comprising at least one feature defining a gap;
a barrier film comprising an alloy of tantalum and a metal dopant selected from the group consisting of ruthenium (Ru), osmium (Os), palladium (Pd), platinum (Pt), and iridium (Ir) on the dielectric layer;
a metal liner film on the barrier film; and
a gap fill metal on the metal liner film.

2. The microelectronic device of claim 1, wherein the metal dopant is present in the barrier film at less than 30 atomic %.

3. The microelectronic device of claim 1, wherein the metal dopant is present in the barrier film at less than 20 atomic %.

4. The microelectronic device of claim 1, wherein the metal dopant comprises ruthenium (Ru).

5. The microelectronic device of claim 4, wherein the ruthenium (Ru) is present in the barrier film at less than 20 atomic %.

6. The microelectronic device of claim 1, wherein the metal dopant comprises osmium (Os).

7. The microelectronic device of claim 6, wherein each of the barrier film and the metal liner film comprise the alloy of tantalum and the metal dopant comprising osmium (Os).

8. The microelectronic device of claim 7, wherein the metal liner film comprising the alloy of tantalum and the metal dopant comprising osmium (Os) improves nucleation of copper compared with a liner film comprising tantalum that does not include osmium (Os).

9. The microelectronic device of claim 1, wherein the barrier film has a thickness in a range of from 8 Å to 10 Å.

10. A method for forming a microelectronic device, the method comprising:
forming a dielectric layer on a substrate, the dielectric layer comprising at least one feature defining a gap;
forming a barrier film on the dielectric layer, the barrier film comprising an alloy of tantalum and a metal dopant selected from the group consisting of ruthenium (Ru), osmium (Os), palladium (Pd), platinum (Pt), and iridium (Ir);
depositing a metal liner film on the barrier film; and
depositing a conductive gap fill metal on the metal liner film.

11. The method of claim 10, wherein the metal dopant is present in the barrier film at less than 20 atomic %.

12. The method of claim 10, wherein the metal dopant is added to prevent formation of a stable nitride in the barrier film.

13. The method of claim 10, wherein the metal dopant has a density that is greater than a density of an undoped barrier film comprising tantalum nitride (TaN).

14. The method of claim 10, wherein the metal dopant comprises ruthenium (Ru).

15. The method of claim 14, wherein the metal dopant comprising ruthenium (Ru) is formed by a chemical vapor deposition (CVD) process.

16. The method of claim 15, wherein forming the alloy of tantalum and the metal dopant comprising ruthenium (Ru) comprises separately co-flowing a tantalum-containing precursor and a ruthenium-containing precursor.

17. The method of claim 16, wherein the tantalum-containing precursor comprises pentakis(dimethylamino)tantalum(V) (PDMAT).

18. The method of claim 10, wherein the metal dopant comprises osmium (Os) formed by an atomic layer deposition (ALD) process.

19. The method of claim 10, wherein forming the barrier film on the dielectric layer further comprises forming a first barrier film on a substrate by atomic layer deposition, doping the first barrier film with a metal dopant by exposing the first barrier film to a metal precursor during a flash chemical vapor deposition process to form a doped first barrier film; and forming a second barrier film on the doped first barrier film by one or more of atomic layer deposition to form a doped barrier film.

20. The method of claim 10, wherein the barrier film comprises substantially no oxygen atoms or carbon atoms.
